(19) United States
(12) Patent Application Publication
(10) Pub. No.: US 2017/0059660 A1
(43) Pub. Date: Mar. 2, 2017

(54) REMOTELY MONITORED BATTERY SYSTEM

(71) Applicant: Draeger Medical Systems, Inc., Andover, MA (US)

(72) Inventors: Lindsay J. Morsillo, Salem, MA (US); Joshua E. Abell, Beverly, MA (US); Michael D. Hirst, Hudson, MA (US); Rand Joseph Monteleone, Acton, MA (US); Alan Edward Alpert, Charlestown, MA (US); Rick J. Niejadlik, North Andover, MA (US); Fnu Vinphin Inasu, Kunduku, Andover, MA (US)

(21) Appl. No.: 14/834,121

(22) Filed: Aug. 24, 2015

(51) Int. Cl. G01R 31/36

(52) U.S. Cl. CPC G01R 31/3606; G01R 31/3648

(57) ABSTRACT

A client device wirelessly receives data including (i) a remaining lifetime and (ii) a charge state of a battery. The data is determined by a battery diagnostic device including a battery gauge, operatively connected to the battery, which measures a stored energy in the battery, and at least one transceiver operatively connected to the battery gauge through a microcontroller. The client device wirelessly relays the received data to a computer system connected to a network to enable the computer system, executing a battery analysis program, to determine an expected charge state of the battery at a future time.

### TECHNICAL FIELD

The subject matter described herein relates to the remote determination of stored energy in electronic devices. Specifically, the determination of a charge state of a battery based on received charge data.

### BACKGROUND

Medical devices requiring portable power supplies, for example batteries, are ubiquitous in modern medical treatment facilities. Medical devices may have their power supplies fully integrated into the medical device, whereas other medical devices may have removable power supplies. Either the medical devices themselves, or batteries used for them, need to be recharged or changed as a result of use. The stored energy in the battery can be determined by medical staff responsible for maintaining the batteries. There can be an indication on the medical device, the charging device, the battery, and so on, of the charge contained in the medical device or battery.

### SUMMARY

In one aspect, a client device wirelessly receives data including (i) a remaining lifetime and (ii) a charge state of a battery. The data is determined by a battery diagnostic device including a battery gauge, operatively connected to the battery, which measures a stored energy in the battery, and at least one transceiver operatively connected to the battery gauge through a microcontroller. The client device wirelessly relays the received data to a computer system connected to a network to enable the computer system, executing a battery analysis program, to determine an expected charge state of the battery at a future time.

In an interrelated aspect, a client device wirelessly receives, by a computer system, data including a remaining lifetime and a charge state of a battery. The data is determined by a battery diagnostic device including a battery gauge, connected to the battery, which measures a stored energy in the battery, and at least one transceiver connected to the battery gauge through a microcontroller. The data is analyzed with a battering analysis program based on historical data to predict an expected discharge rate of the battery. The expected discharge rate is used to determine the expected charge state of the battery at a future time. The battery analysis program provides the expected charge state to the battery management program. The computer system displays the expected charge state in a configuration interface. The computer system wirelessly transmits, to the client device, an expected charge state of the battery at the future time.

In an interrelated aspect, a remaining lifetime and a charge state of a battery are determined by a battery diagnostic device including a battery gauge, connected to the battery, which measures a stored energy in the battery, and a transceiver operatively connected to the battery gauge through a microcontroller. The transceiver wirelessly transmits data including the remaining lifetime and the charge state to a client device.

In some variations, the client device can provide, based on the received data, an indication of the charge state of the battery. The indication can include a graphical element rendered in a graphical user interface displayed on the client device. The indication can include an audio element. The client device can be a cellular telephone, a tablet computer, and a laptop computer. The client device can analyze the data based on historical data to predict an expected discharge rate of the battery. The expected discharge rate can be used to determine the expected charge state of the battery at the future time. The client device can display the expected charge state in the graphical user interface displayed on the client device. A replacement interval can be determined from the expected charge rate. The replacement interval can be displayed by the client device in the graphical user interface displayed on the client device.

The client device can associate a medical device with the battery based on a first identity corresponding to the battery and a second identity corresponding to the medical device. The client device can wirelessly transmit, to the computer system, the first identity, the second identity, and the data. The client device can wirelessly receive, from the computer system, a second expected lifetime of the medical device based on the data, including the charge state of the battery, and the second identity. The receiving and the relaying can be by at least one of low-energy wireless, wireless, or a local area network.

The determination by the battery analysis program can include accessing historical data to determine the expected charge state at the future time, calculating, based on the historical data and the data including the remaining lifetime and the charge state of the battery, the expected charge state at the future time, and providing the expected charge state at the future time to the client device, the battery management program, and/or a configuration interface. The historical data can include a discharge curve for the battery, a discrete data point corresponding to the charge state of the battery, a periodic record corresponding to a historical charge state of the battery, or a nominal battery lifetime. The client device can wirelessly receive, from the computer system, the expected charge state of the battery at the future time.

An alert can be provided, by the client device and based on the charge state of the battery, when the remaining lifetime of the battery is below a predetermined length of time, when the battery is below a predetermined charge state, or includes a failure condition.

The battery diagnostic device can include the battery. Alternatively, the battery can be external to the battery diagnostic device.

A configuration interface can be generated by the computer system to associate at least one battery diagnostic device with the medical device to which the battery diagnostic device is connected. Received data corresponding to the associated battery diagnostic device can be loaded into the configuration interface. The received data can be analyzed by the battery analysis program based on historical data to predict an expected discharge rate of the battery. The expected discharge rate can be used to determine the expected charge state of the battery at the future time. The configuration interface can display the expected charge state.

The battery diagnostic device can wirelessly transmit the data to at least one mobile client device. The wirelessly transmitting can include first transmitting, at a first time to a first mobile client device, first data including the remaining lifetime and the charge state of the battery. The wirelessly transmitting can also include second transmitting, at a second time subsequent to the first time and to a second mobile client device, second data including the remaining lifetime and the charge state of the battery at the second time. The first transmitting and/or the second transmitting can occur when the at least one mobile client device is within a transmission range of the battery diagnostic device. The one mobile client device is not a single, fixed-location, client device. The one mobile client device can be a smartphone or a tablet computer.

Implementations of the current subject matter can include, but are not limited to, methods consistent with the descriptions provided herein as well as articles that comprise a tangibly embodied non-transient machine-readable medium operable to cause one or more machines (e.g., computers, etc.) to result in operations implementing one or more of the described features. Similarly, computing systems are also described that may include one or more processors and one or more memories coupled to the one or more processors. A memory, which can include a computer-readable storage medium, may include, encode, store, or the like one or more programs that cause one or more processors to perform one or more of the operations described herein. Computer implemented methods consistent with one or more implementations of the current subject matter can be implemented by one or more data processors residing in a single computing system or multiple computing systems. Such multiple computing systems can be connected and can exchange data and/or commands or other instructions or the like via one or more connections, including but not limited to a connection over a network (e.g. the Internet, a wireless wide area network, a local area network, a wide area network, a wired network, or the like), via a direct connection between one or more of the multiple computing systems, etc.

Implementations of the current subject matter can provide one or more technical advantages. For example, a client device, such as a mobile phone, laptop computer, and so on, can receive data that indicates a charge state of a nearby battery. The client device can also act as a relay to send the charge state to a computer system that monitors the charge state of a number of such batteries throughout a facility.

The details of one or more variations of the subject matter described herein are set forth in the accompanying drawings and the description below. Other features and advantages of the subject matter described herein will be apparent from the description and drawings, and from the claims. While certain features of the currently disclosed subject matter are described for illustrative purposes in relation to a battery charge indicator, it should be readily understood that such features are not intended to be limiting unless otherwise specified. The claims that follow this disclosure are intended to define the scope of the protected subject matter.

### DESCRIPTION OF DRAWINGS

The accompanying drawings, which are incorporated in and constitute a part of this specification, show certain aspects of the subject matter disclosed herein and, together with the description, help explain some of the principles associated with the disclosed implementations. In the drawings,

FIG. 1 is a process flow diagram illustrating a client device receiving data from a battery diagnostic device and providing an indication of a charge state of a battery;

FIG. 2 is a diagram illustrating a client device relaying data from a battery diagnostic device to a computer system;

FIG. 3 is a process flow diagram illustrating monitoring and analysis, by the computer system, of received data from a battery diagnostic device;

FIG. 4 is a process flow diagram illustrating determining a second expected lifetime of a battery based on an identity of a battery and an identity of a medical device;

FIG. 5 is a diagram illustrating a battery diagnostic device with an integrated battery;

FIG. 6 is a diagram illustrating a battery diagnostic device with a battery external to the battery diagnostic device;

FIG. 7 is a diagram illustrating a first mobile client device and a second mobile client device relaying data from a battery diagnostic device to a network; and

FIG. 8 is a signal diagram illustrating a second mobile client device relaying data from a battery diagnostic device to a network subsequent to a first mobile client device relaying data from a battery diagnostic device to a network.

When practical, similar reference numbers denote similar structures, features, or elements.

### DETAILED DESCRIPTION

The current subject matter provides a battery diagnostic device that easily communicates to a user the remaining lifetime and/or a charge state of connected medical devices and/or batteries. The charge state can describe the amount of charge or stored energy in a medical device or battery. For example, the charge state can be expressed as a percentage of: a maximum lifetime, a maximum amount of stored energy, etc.

Also, the “medical device” can be a device for measuring a physiological condition of a patient, may be used in connection with the treatment, and/or care of a patient, and can include at least one battery for providing power. While the current subject matter is described in connection with medical devices, it will be appreciated that the current subject matter can apply to other types of battery-powered electronic devices including trace gas detectors and other measurement systems.

Portable medical devices, common to hospitals, clinics, and other caregiving facilities, can be used for the diagnosis or treatment of patients or for measuring a patient's physiological parameters. Medical devices can contain batteries, which are depleted over time through use or natural dissipation. Caregivers must continuously monitor the batteries to know if a battery needs charging or replacing. If not properly monitored, the charge state of a battery can be insufficient for a given medical procedure. For example, a device that needs a full charge to be used for a long procedure would need charging even if mostly charged. Such determinations of the charge states of batteries can be done by medical staff, but this can be a time-consuming and inexact process. The current subject matter can have batteries and/or medical devices connected to a battery diagnostic device that wirelessly transmits this information to nearby client devices, for example, cell phones, tablet computers, etc.

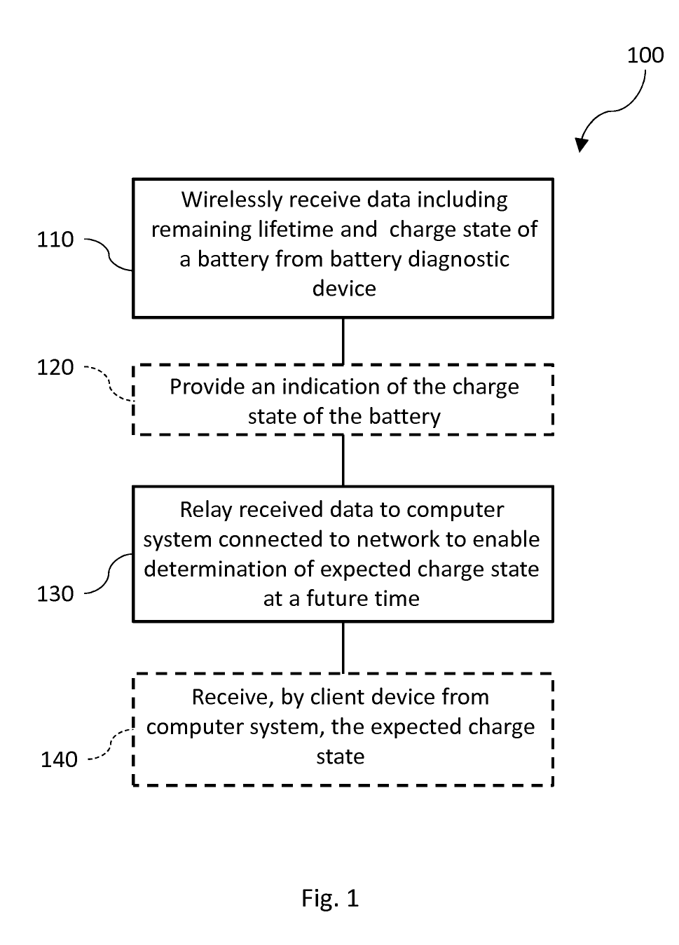

FIG. 1 is a process flow diagram 100 illustrating a client device receiving data from a battery diagnostic device and providing an indication of a charge state of a battery.

At 110, the data transmitted wirelessly by the battery diagnostic device can be received by the client device and include a remaining lifetime and a charge state of a battery. The received data can allow determination of battery charge states automatically and continuously.

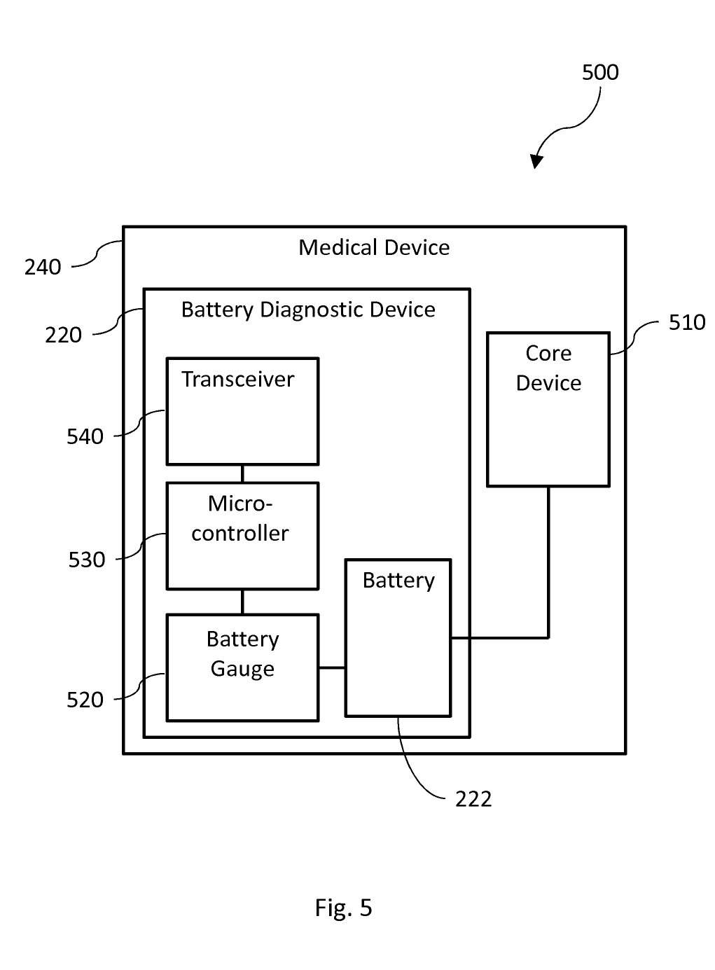

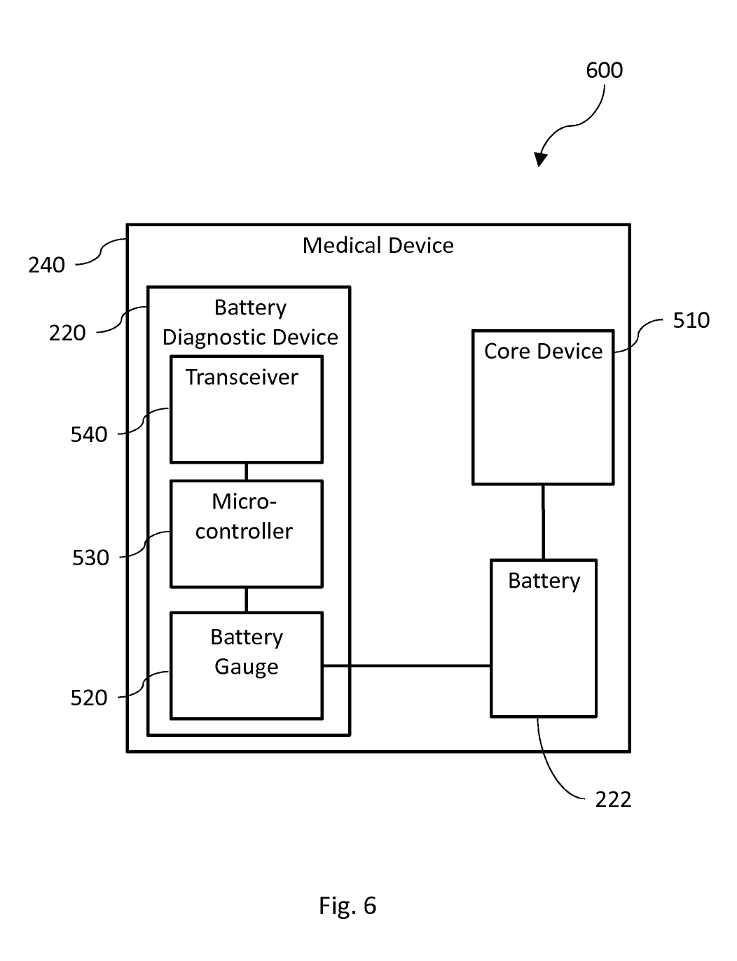

The battery diagnostic device can include a battery gauge connected to the battery, a transceiver, and a microcontroller. The battery gauge can be a circuit that can measure stored energy in the battery. Based on the measured stored energy in the battery, the charge state of the battery can be determined. The transceiver can transmit and receive data, provided by the battery gauge, to or from, for example, nearby client devices, routers, wireless hubs, other battery diagnostic devices, etc. The data can include, for example, the stored energy, charge state, remaining lifetime, etc. Details of some implementations of the battery diagnostic device are illustrated in FIGS. 5 and 6 and further described below.

Optionally, at 120, the client device can provide, based on the received data, an indication of the charge state of the battery rendered in a graphical user interface displayed on the client device. The indication can be provided by a computer program or application. The application can be of the sort common to mobile devices, allowing for user interaction with the indication. For example, the data can be analyzed and examined in greater detail, sent to another device, stored in the memory of the client device, etc. The indication can include a graphical element, for example, text, images, icons, animations, etc. The indication can also include an audio element, for example, sound communicating a remaining charge, an alert, an estimated lifetime, etc. The audio element can be, for example, words, tones, beeps, etc.

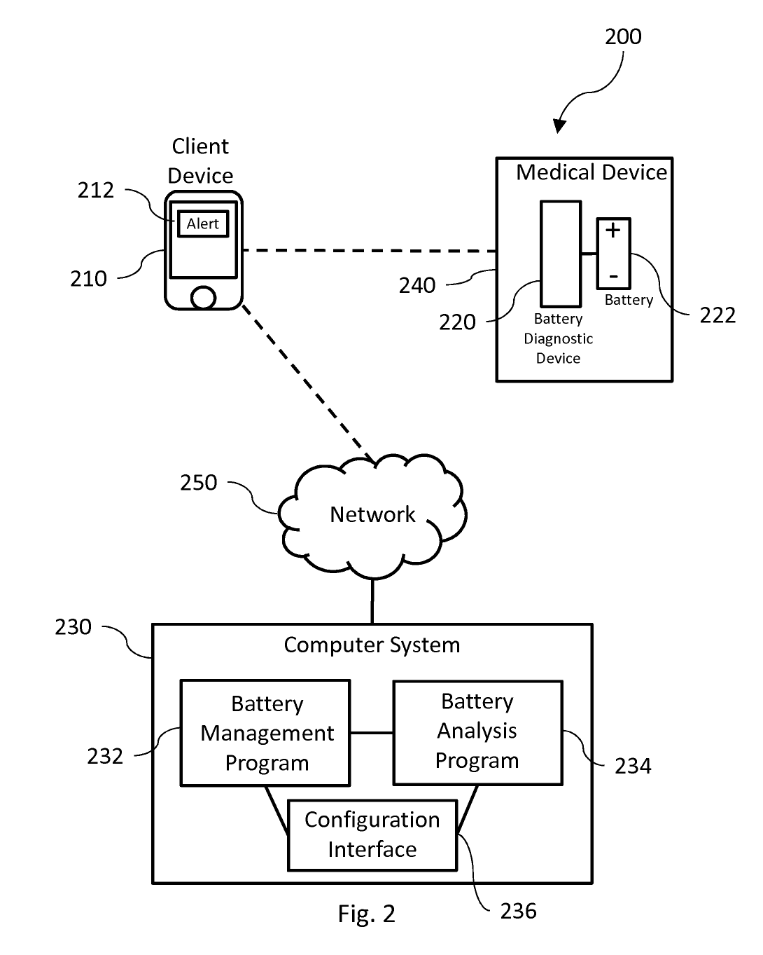

At 130, the client device can wirelessly relay the received data to a computer system connected to a network to enable a computer system, executing a battery analysis program, to determine an expected charge state of the battery at a future time. The relaying can be over one or more network connections. The data from the battery diagnostic device can be transmitted to the client device directly through, for example, a cellular telephone network, to a wireless router, low-energy communications such as BLUETOOTH low energy or Near-Field Communication (NFC), etc. In turn, the client device can transmit or relay the data to the computer system by, for example, a cellular telephone network, BLUETOOTH low energy, WIFI, LAN, WLAN, NFC, etc. The computer system receiving the data can be, for example, a mainframe computer, a server, a database, a central management system, a desktop computer, etc. Further details of the connected battery diagnostic device/client device/computer system are described in FIG. 2.

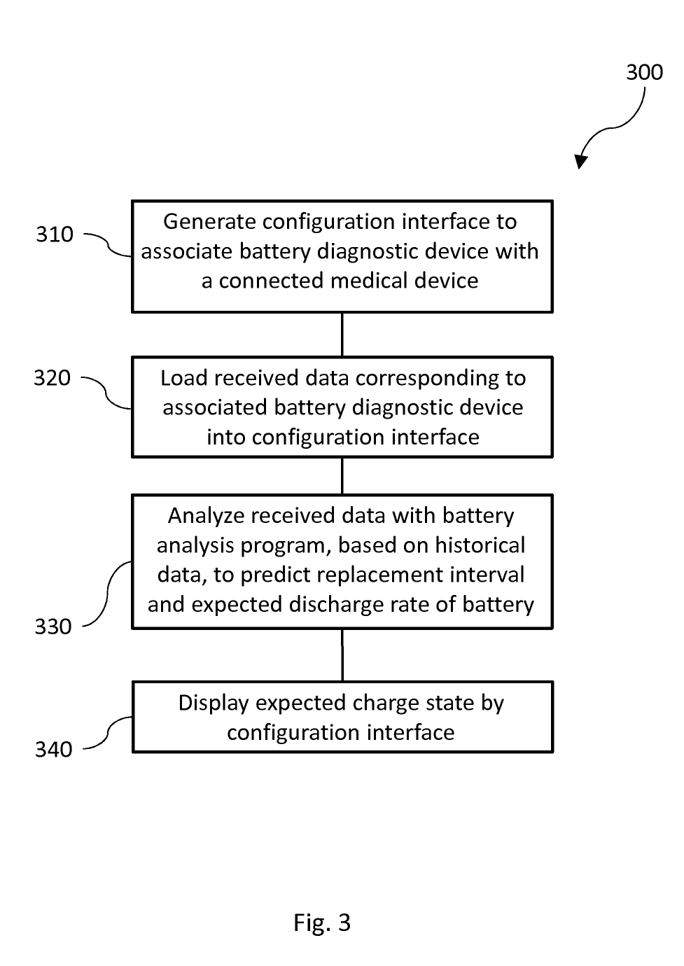

Optionally, at 140, the client device can wirelessly receive an expected charge state of the battery at a future time from a computer system. The expected charge state can be determined by the computer system as described in FIGS. 2 and 3. The expected charge state at a future time can, for example, be determined from a known discharge curve. This determination can also take into account information about scheduled procedures that use the medical device. For example, a medical database can be accessed that has scheduled surgeries or treatments, expected duration, device usage during the procedures, etc. By taking into account the existing charge state, as well as historical data on discharge during the procedures, it can be determined if the battery will be sufficiently charged when needed.

FIG. 2 is a diagram 200 illustrating a client device 210 relaying data from a battery diagnostic device 220 to a computer system 230. One implementation of the system described herein can include at least one medical device 240, at least one client device 210, and at least one computer system 230 connected to a network 250. The medical device 240 can have at least one battery 222 connected to a battery diagnostic device 220. However, the medical device 240 can also have more than one battery 222. In the case of multiple batteries, the battery diagnostic device 220 can monitor the overall charge state of the connected batteries, or monitor the charge state of each individual battery 222. The battery diagnostic device 220 can further include a transceiver that can transmit data to the client device 210. The data transmitted between the client device 210, the battery diagnostic device 220, and the computer system 230, can be sent by, for example, NFC, BLUETOOTH low-energy, WIFI, LAN, WLAN, peer-to-peer network, etc.

Though shown in FIG. 2 as a smartphone, the client device 210 can be, for example, a cellular telephone, a tablet computer, a laptop computer, a desktop computer, a server, etc. However, in some implementations, it can be desirable for the battery diagnostic device 220 to be in communication only with mobile client devices, and not with fixed-location client devices or computing systems such as workstations, servers, central stations, etc. In this implementation, examples of mobile client devices can include cellular telephones, tablet computers, laptop computers, etc.

The client device 210 can act as a relay that sends data received from battery diagnostic devices 220, proximate to the client device 210, to the network 250 and connected computer systems 230. Such relays can be useful when, for example, the battery diagnostic device 220 transmits using short-range transmission methods, for example, BLUETOOTH low-energy or NFC. Also, the client device 210 can provide, via an application or ‘app’ running on the client device 210, information about the received data. The client device 210 can provide an alert based on the charge state of the battery 222 when the remaining lifetime of the battery 222 is below a predetermined length of time. The alert or other information about the battery 222 or the medical device 240 can be displayed as a graphical element 212 on a device screen. The app can also periodically upload a list of batteries and other status information as the client device 210 becomes proximate enough to the batteries to allow upload. The data received can be time-stamped to allow the data to be properly integrated with the battery management program 232 when the data is uploaded to the computer system 230.

The computer system 230 can receive data from the client device 210 via the network 250. The received data can be analyzed and monitored by a battery management program 232, battery analysis program 234, and a configuration interface 236, all illustrated in FIG. 3 and further described below. Once analyzed, information such as the charge state, a replacement interval, an expected charge state at a future time, an alert, and so on, can be transmitted to the client device 210 and displayed in a graphical user interface. The computer system 230, after analyzing received data about the charge state of a battery 222, can issue an alert for immediate action or distribution. Any of the alerts described herein can be based on, for example, preconfigured rules or expected battery life calculations. Preconfigured rules can include, for example, the charge state of the battery 222 being below a certain level, a determination that an expected lifetime of the battery 222 is insufficient for a procedure, etc. Expected battery life calculations can be performed either by, for example, the client device 210 or the computer system 230 to determine or estimate when a battery 222 is going to be depleted. Based on the expected better life calculations, an alert can be issued or distributed.

FIG. 3 is a process flow diagram 300 illustrating monitoring and analysis, by the computer system 230, of received data from a battery diagnostic device 220. As mentioned in FIG. 2, the computer system 230 can have a battery management program 232 that can act as a central hub to display information about the status of a collection of monitored medical devices and/or batteries.

According to one implementation, at 310, a configuration interface 236 can be generated by the computer system 230 to associate at least one battery diagnostic device 220 with the medical device 240 to which the battery diagnostic device 220 is connected. The received data can include information specifying that a particular battery 222 is being used in, for example, a portable patient monitor. This information can include details about the battery 222, the connected medical device 240, location of the battery 222, location and identity of the client device 210, information associated with a patient, etc. The identity, as well as any alerts or other event flags, can be transmitted as, for example, a 16 bit number.

At 320, received data corresponding to the associated battery diagnostic device 220 can be loaded into the configuration interface 236. More particularly, for example, the loading can be into the battery management program 232 executing the configuration interface 236. The data can also be stored in a persistent memory, for example, a hard drive, a database, cloud storage, RAM, saved to physical disc or flash memory, etc. The configuration interface 236 can access the persistent memory as needed to display or analyze the data.

At 330, a battery analysis program 234 can analyze the received data based on historical data to calculate a replacement interval and an expected discharge rate of the battery 222. The historical data can include, for example, discharge curves for batteries measured during various medical procedures or other use conditions, discrete data points (start values and end values) of the charge state between two points in time, periodic records (daily, weekly, monthly, etc.), nominal battery lifetimes, for example those measured by the manufacturer, statistics on battery usage, etc. The historical data accessed can include simulated discharge rates for known procedures or usage of the battery 222. For example, if a medical device 240 consumes energy at a known rate, then the expected charge state of the battery 222 at a future time can be predicted. The historical data can provide corrections or supplemental data based on recorded factors. For example, if a battery 222 would normally be rated to last 4 hours under certain conditions, but in 90% of the cases of use the battery 222 only lasts 3 hours, this information can be accessed when determining whether to provide an alert or request a battery change. Also, changes in the measured discharge curves of batteries currently in use can indicate batteries that are aging or defective. Information about the expected charge state can be provided to the client device 210, the battery management program 232 and/or a configuration interface 236.

The battery analysis program 234 can provide, based on the replacement interval and/or the expected discharge rate, an alert when the battery 222 is below a predetermined charge state or includes a failure condition. The alert can be provided when the battery 222 is below a predetermined charge state. The predetermined charge state can be, for example, below 50% charge, below 10% charge, etc. The failure condition can be, for example, detecting that a battery 222 is not connected, has a connection problem, or is discharging faster than expected. If a battery 222 is not connected, then the charge state of the battery 222 may be higher than expected, indicating an error. If a battery 222 is intermittently connected, then again, the charge state can be higher than expected. Also, an intermittent connection can be observed by discontinuities or electronic errors in reporting the charge state. Similarly, if a battery 222 is discharging faster than expected, it could indicate a defective battery, a battery being used more than expected or in a different mode than is expected, the battery 222 being in the wrong medical device 240, a problem with the medical device 240 itself, etc. The battery analysis program 234 can also incorporate data from scheduled procedures or simulated power use to determine if a battery 222 needs to be charged or changed. The battery analysis program 234 can also provide information on what batteries or medical devices 240 to use in a particular scenario given the parameters of expected use.

At 340, the configuration interface 236 can display, for example, the charge state, the replacement interval, the expected discharge rate, the alert, etc. The displaying can be as a graphical user interface shown on a computer screen, graphical elements in an app, a light or light emitting diode (LED) on a status panel, etc.

The functions described above for the battery management program 232 and the battery analysis program 234 can also be implemented on the client device 210. For example, an app running on a client device 210, such as a smartphone, can perform some or all of the features of the battery analysis program 234. The client device 210, computer system 230, etc., can include a battery census listing a known inventory of batteries and their charge states. Also, historical data can be uploaded to the client device 210 at periodic intervals to allow estimations of discharge rates and future charge states to be determined locally.

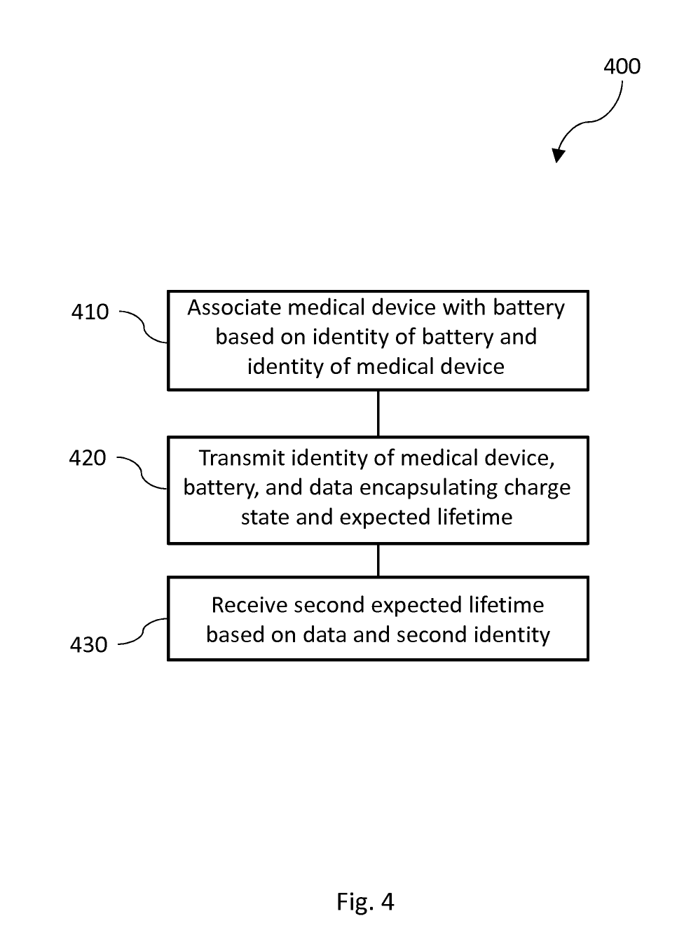

FIG. 4 is a process flow diagram 400 illustrating determining a second expected lifetime of a battery 222 based on an identity of a battery 222 and an identity of a medical device 240.

At 410, a medical device 240 can be associated with the battery 222 based on a first identity corresponding to the battery 222 and a second identity corresponding to the medical device 240. Examples of the first identity can include, for example, the type of battery, the model of the battery, etc. Examples of the second identity of the medical device 240 can include, for example, a defibrillator, a portable patient monitor, a respirator, etc. The first identity and or the second identity can be expressed as identifying data capturing the aforementioned information. For example, identifying data corresponding to first identity and/or the second identity can be database records, product codes, etc. The association can be performed by, for example, the battery diagnostic device 220, the client device 210, the computer system 230, etc. The association can involve, for example, a radio-frequency identification (RFID) detection of the medical device 240 using the battery 222, a visual confirmation and manual entry of the second identity to the client device 210, the battery management program 232 associating the battery 222 and the medical device 240 and storing the association in memory, etc.

At 420, the client device 210 can transmit the first identity, the second identity, and the data to the computer system 230. The transmission can be wired or wireless, and through the network 250, for example, a cellular network, a WLAN, etc.

At 430, after the analysis described in FIG. 3, the client device 210 can wirelessly receive a second expected lifetime of the medical device 240 from the computer system 230. The second expected lifetime can be an updated lifetime based on the data, including the charge state of the battery 222, and the second identity.

FIG. 5 is a diagram 500 illustrating a battery diagnostic device 220 with an integrated battery 222. In one implementation, the battery diagnostic device 220 can have the battery 222 internal to, or integrated with, the battery diagnostic device 220. In this implementation, the battery 222 can be considered a “smart” battery that is able to communicate, via the transceiver 540 in the battery diagnostic device 220, information about its charge state or connection to the medical device 240.

In the example shown in FIG. 5, the medical device 240 is shown as including the battery diagnostic device 220 and a core device 510. The core device 510 is the part of the medical device 240 that excludes the battery 222 and the battery diagnostic device 220. The battery 222 can be connected to the core device 510 to provide power for use. The battery diagnostic device 220, in this implementation, can include the battery 222, a battery gauge 520, a microcontroller 530, and a transceiver 540. The battery gauge 520 can measure the stored energy of the battery 222. This can be done by measuring the voltage across battery terminals or other connection nodes, connecting a shunt resistor to the circuit, measuring the impedance of the battery 222, or measuring currents through connected conductors with voltage detectors, Hall probes, etc.

The microcontroller 530 can be an integrated circuit or other electronic hardware that allows the battery gauge 520 to interface with the transceiver 540. The microcontroller 530 can include data processors, analog-to-digital converter (ADC) circuitry, or other transistor logic components to convert the measured signals from the battery gauge 520 to a form that can be transmitted by the transceiver 540.

The transceiver 540 can be any kind of transmitter, receiver, or combination thereof that transmits data communicating the charge state of the battery 222. The transceiver 540 can be configured to work with, for example, wireless routers, BLUETOOTH low-energy, cellular networks, NFC, WLAN, etc.

FIG. 6 is a diagram 600 illustrating a battery diagnostic device 220 with a battery 222 external to the battery diagnostic device 220. Though similar to FIG. 5, the implementation shown in FIG. 6 illustrates what can be considered a “retrofitted” medical device 240. Here, in this example, the medical device 240 and/or battery 222 was never intended to have a battery diagnostic device 220 incorporated for use. The battery diagnostic device 220 can then be added to the existing battery 222 to function substantially similar to that described throughout this application. For the implementations shown in both FIGS. 5 and 6, any of the components of the medical device 240, the battery diagnostic device 220, and battery 222, can be connected as needed to perform the operations described herein.

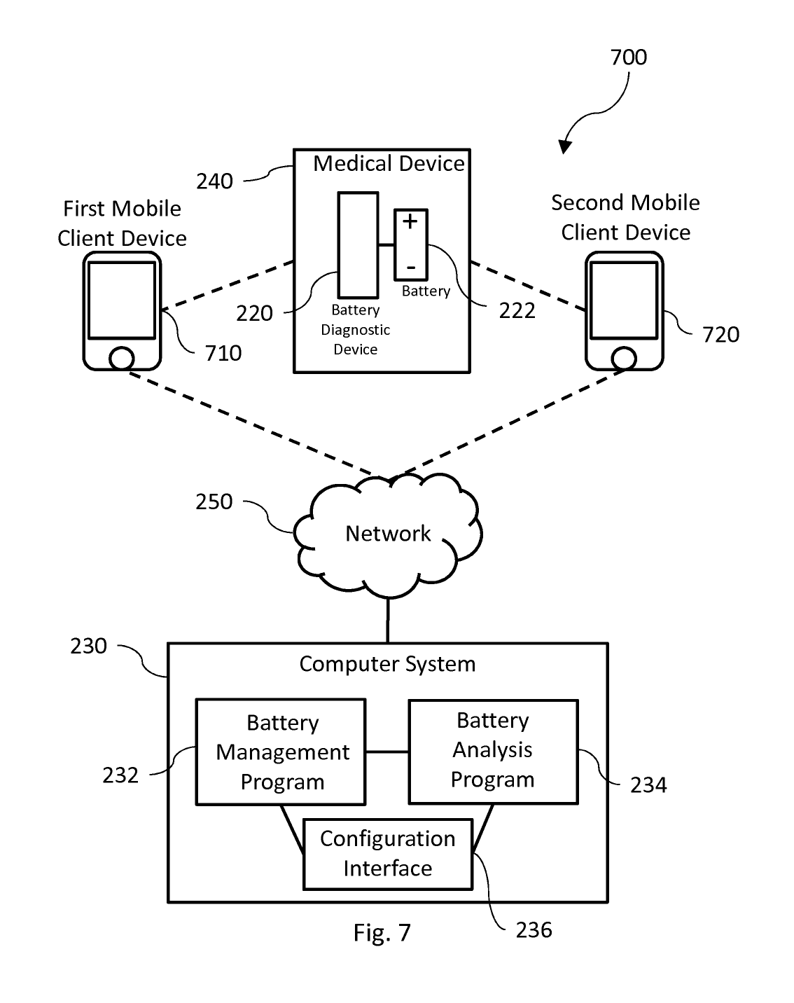

FIG. 7 is a diagram illustrating a first mobile client device 710 and a second mobile client device 720 relaying data from a battery diagnostic device 220 to a network 250. As described herein, the data can include the charge state and/or the remaining lifetime of the battery connected to the medical device 240. The data can then be relayed by the network 250 to the computer system 230. The computer system 230 can remain updated as to the charge state and/or remaining lifetimes of batteries in the system by receiving periodic updates from mobile client devices when they are near the battery diagnostic device 220. While two mobile client devices are shown in FIG. 7, there can be any number of mobile client devices that are in communication with the battery diagnostic device 220.

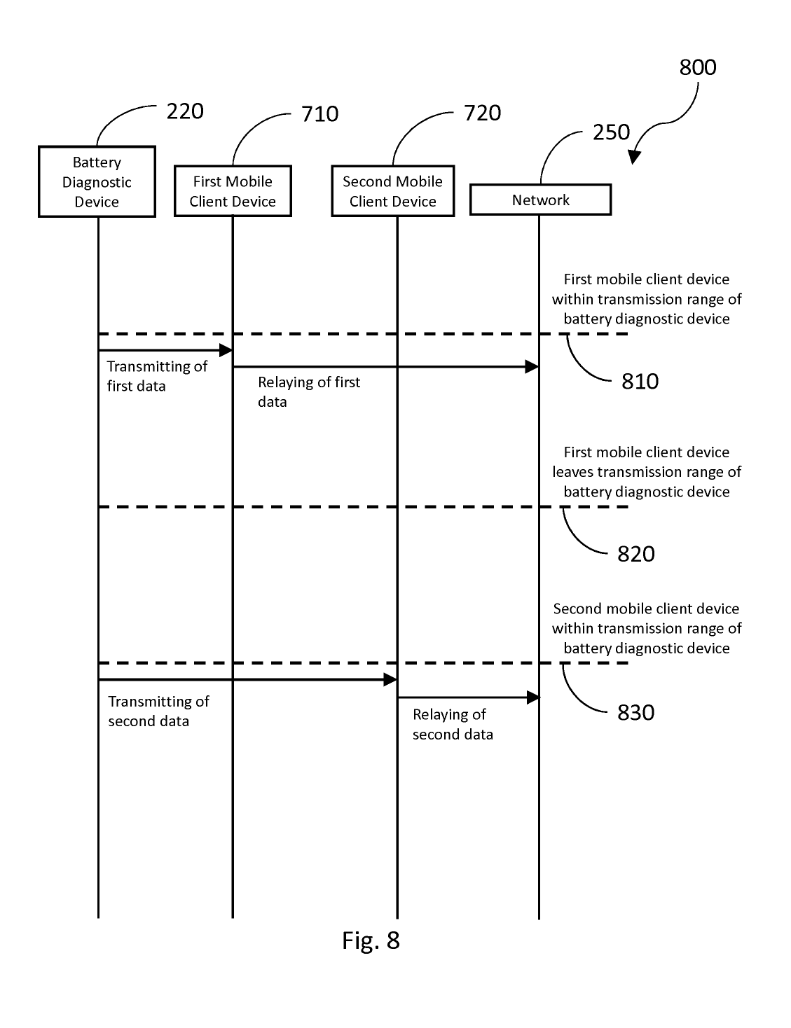

The battery diagnostic device 220 can transmit data about the charge state of the battery 222 to one or more mobile client devices either sequentially or simultaneously. In one implementation, there can be a first transmitting, at a first time to a first mobile client device 710 of first data including the remaining lifetime and the charge state of the battery 222. The first transmitting can occur when the first mobile client device 710 first comes within transmission range of the battery diagnostic device 220. In another implementation, the battery diagnostic device 220 can transmit data about the charge state of the battery 222 continuously which would be received by a mobile client device whenever a mobile client device is within a transmission range of the battery diagnostic device 220. Later, there can be a second transmitting, at a second time subsequent to the first time and to a second mobile client device 720, of second data including the remaining lifetime and the charge state of the battery 222 at the second time. These features are further described by the signal diagram shown in FIG. 8.

FIG. 8 is a signal diagram illustrating a second client device 720 relaying data from a battery diagnostic device 220 to a network 250 subsequent to a first client device 710 relaying data from the battery diagnostic device 220 to a network 250. In the exemplary sequence shown in FIG. 8, at 810, the first mobile client device 710 can come within transmission range of the battery diagnostic device 220. At this time, the battery diagnostic device 220 can transmit the first data to the first mobile client device 710. The first mobile client device 710 can then relay the first data to the network 250.

At 820, the first mobile client device 710 can leave the transmission range of the battery diagnostic device 220.

At 830, at a subsequent time, a second mobile client device 720, can come within transmission range of the battery diagnostic device 220. At the subsequent time, the battery diagnostic device 220 can transmit second data to the second mobile client device 720. The second data can include a current charge state and/or remaining lifetime of the battery 222. The second mobile client device 720 can then relay the second data to the network 250. While the exemplary diagram of FIG. 8 describes a first mobile client device 710 relaying first data and then a second mobile client device 720 relaying second data, there can be any number of mobile client devices that relay data in a manner similar to that shown.

In one implementation, the second mobile client device 720 can receive second data from the battery diagnostic device 220 before the first mobile client device 710 has left transmission range. In this example, the first mobile client device 710 can continue to receive first data from the battery diagnostic device 220 while the second mobile client device 720 receives second data from the battery diagnostic device. In the event that more than one mobile client device receives data from the battery diagnostic device 220, the data received by both mobile client devices would be substantially identical as the data reflects a nearly identical charge state of the battery 222. In this way, the transmission of data from the battery diagnostic device 220 can occur sequentially, or in an overlapping manner, to one or more mobile client devices.

One or more aspects or features of the subject matter described herein can be realized in digital electronic circuitry, integrated circuitry, specially designed application specific integrated circuits (ASICs), field programmable gate arrays (FPGAs) computer hardware, firmware, software, and/or combinations thereof. These various aspects or features can include implementation in one or more computer programs that are executable and/or interpretable on a programmable system including at least one programmable processor, which can be special or general purpose, coupled to receive data and instructions from, and to transmit data and instructions to, a storage system, at least one input device, and at least one output device. The programmable system or computing system may include clients and servers. A client and server are generally remote from each other and typically interact through a communication network. The relationship of client and server arises by virtue of computer programs running on the respective computers and having a client-server relationship to each other.

These computer programs, which can also be referred to programs, software, software applications, applications, components, or code, include machine instructions for a programmable processor, and can be implemented in a high-level procedural language, an object-oriented programming language, a functional programming language, a logical programming language, and/or in assembly/machine language. As used herein, the term “machine-readable medium” refers to any computer program product, apparatus and/or device, such as for example magnetic discs, optical disks, memory, and Programmable Logic Devices (PLDs), used to provide machine instructions and/or data to a programmable processor, including a machine-readable medium that receives machine instructions as a machine-readable signal. The term “machine-readable signal” refers to any signal used to provide machine instructions and/or data to a programmable processor. The machine-readable medium can store such machine instructions non-transitorily, such as for example as would a non-transient solid-state memory or a magnetic hard drive or any equivalent storage medium. The machine-readable medium can alternatively or additionally store such machine instructions in a transient manner, such as for example as would a processor cache or other random access memory associated with one or more physical processor cores.

To provide for interaction with a user, one or more aspects or features of the subject matter described herein can be implemented on a computer having a display device, such as for example a cathode ray tube (CRT) or a liquid crystal display (LCD) or a light emitting diode (LED) monitor for displaying information to the user and a keyboard and a pointing device, such as for example a mouse or a trackball, by which the user may provide input to the computer. Other kinds of devices can be used to provide for interaction with a user as well. For example, feedback provided to the user can be any form of sensory feedback, such as for example visual feedback, auditory feedback, or tactile feedback; and input from the user may be received in any form, including, but not limited to, acoustic, speech, or tactile input. Other possible input devices include, but are not limited to, touch screens or other touch-sensitive devices such as single or multi-point resistive or capacitive trackpads, voice recognition hardware and software, optical scanners, optical pointers, digital image capture devices and associated interpretation software, and the like.

In the descriptions above and in the claims, phrases such as “at least one of” or “one or more of” may occur followed by a conjunctive list of elements or features. The term “and/or” may also occur in a list of two or more elements or features. Unless otherwise implicitly or explicitly contradicted by the context in which it used, such a phrase is intended to mean any of the listed elements or features individually or any of the recited elements or features in combination with any of the other recited elements or features. For example, the phrases “at least one of A and B;” “one or more of A and B;” and “A and/or B” are each intended to mean “A alone, B alone, or A and B together.” A similar interpretation is also intended for lists including three or more items. For example, the phrases “at least one of A, B, and C;” “one or more of A, B, and C;” and “A, B, and/or C” are each intended to mean “A alone, B alone, C alone, A and B together, A and C together, B and C together, or A and B and C together.” Use of the term “based on,” above and in the claims is intended to mean, “based at least in part on,” such that an unrecited feature or element is also permissible.

The subject matter described herein can be embodied in systems, apparatus, methods, and/or articles depending on the desired configuration. The implementations set forth in the foregoing description do not represent all implementations consistent with the subject matter described herein. Instead, they are merely some examples consistent with aspects related to the described subject matter. Although a few variations have been described in detail above, other modifications or additions are possible. In particular, further features and/or variations can be provided in addition to those set forth herein. For example, the implementations described above can be directed to various combinations and subcombinations of the disclosed features and/or combinations and subcombinations of several further features disclosed above. In addition, the logic flows depicted in the accompanying figures and/or described herein do not necessarily require the particular order shown, or sequential order, to achieve desirable results. Other implementations may be within the scope of the following claims.

What is claimed is:

1. A method comprising:
wirelessly receiving, by a client device, data including (i) a remaining lifetime and (ii) a charge state of a battery, the data determined by a battery diagnostic device comprising: a battery gauge, operatively connected to the battery, which measures a stored energy in the battery, and at least one transceiver operatively connected to the battery gauge through a microcontroller; and
wirelessly relaying, by the client device, the received data to a computer system connected to a network to enable the computer system, executing a battery analysis program, to determine an expected charge state of the battery at a future time.

2. The method of claim 1, further comprising:
providing, by the client device and based on the received data, an indication of the charge state of the battery, the indication comprising a graphical element rendered in a graphical user interface displayed on the client device.

3. The method of claim 1, further comprising:
wirelessly receiving, by the client device from the computer system, the expected charge state of the battery at the future time.

4. The method of claim 1, further comprising:
associating, by a client device, a medical device with the battery based on a first identity corresponding to the battery and a second identity corresponding to the medical device;
wirelessly transmitting, to the computer system from the client device, the first identity, the second identity, and the data; and
wirelessly receiving, by the client device from the computer system, a second expected lifetime of the medical device based on the data, including the charge state of the battery, and the second identity.

5. The method of claim 1, wherein the determination by the battery analysis program comprises:
accessing historical data to determine the expected charge state at the future time;
calculating, based on the historical data and the data including the remaining lifetime and the charge state of the battery, the expected charge state at the future time; and
providing the expected charge state at the future time to the client device, the battery management program, and/or a configuration interface.

6. The method of claim 5, the historical data comprising at least one of: a discharge curve for the battery, a discrete data point corresponding to the charge state of the battery, a periodic record corresponding to a historical charge state of the battery, or a nominal battery lifetime.

7. The method of claim 1, further comprising providing an alert, by the client device and based on the charge state of the battery, when the remaining lifetime of the battery is below a predetermined length of time.

8. The method of claim 1, wherein the receiving and the relaying is by at least one of low-energy wireless, wireless, or a local area network.

9. The method of claim 1, wherein the client device is selected from a group consisting of: a cellular telephone, a tablet computer, and a laptop computer.

10. The method of claim 2, wherein the indication further comprises an audio element.

11. The method of claim 2, further comprising:
analyzing, by the client device, the data based on historical data to predict an expected discharge rate of the battery, wherein the expected discharge rate is used to determine the expected charge state of the battery at the future time; and
displaying, by the client device, the expected charge state in the graphical user interface displayed on the client device.

12. The method of claim 1, further comprising providing an alert when the battery is below a predetermined charge state or includes a failure condition.

13. The method of claim 2, further comprising:
determining, from the expected discharge rate, a replacement interval; and
displaying, by the client device, the replacement interval in the graphical user interface displayed on the client device.

14. The method of claim 1, wherein the battery diagnostic device further comprises the battery.

15. The method of claim 1, wherein the battery is external to the battery diagnostic device.

16. A method comprising:
wirelessly receiving, by a computer system from a client device, data including a remaining lifetime and a charge state of a battery, the data determined by a battery diagnostic device comprising: a battery gauge, operatively connected to the battery, which measures a stored energy in the battery, and at least one transceiver operatively connected to the battery gauge through a microcontroller;
analyzing, with a battery analysis program, the data based on historical data to predict an expected discharge rate of the battery, wherein the expected discharge rate is used to determine the expected charge state of the battery at a future time;
providing, by the battery analysis program, the expected charge state to the battery management program;
displaying, by the computer system, the expected charge state in a configuration interface; and
wirelessly transmitting, from the computer system to the client device, an expected charge state of the battery at the future time.

17. The method of claim 14, further comprising:
generating a configuration interface by the computer system to associate at least one battery diagnostic device with the medical device to which the battery diagnostic device is connected;
loading the received data corresponding to the associated battery diagnostic device into the configuration interface;
analyzing, by the battery analysis program, the received data based on historical data to predict an expected discharge rate of the battery, wherein the expected discharge rate is used to determine the expected charge state of the battery at the future time; and
displaying, by the configuration interface, the expected charge state.

18. A system comprising:
at least one programmable processor; and
a memory storing instructions which, when executed by the at least one programmable processor, cause the at least one programmable processor to perform operations comprising:
wirelessly receiving, by a client device, data including a remaining lifetime and a charge state of a battery, the data determined by a battery diagnostic device comprising: a battery gauge, operatively connected to the battery, which measures a stored energy in the battery, and at least one transceiver operatively connected to the battery gauge through a microcontroller; and
wirelessly relaying, by the client device, the received data to a computer system connected to a network to enable the computer system, executing a battery analysis program, to determine an expected charge state of the battery at a future time.

19. The system of claim 18, further comprising:
associating, by a client device, a medical device with the battery based on a first identity corresponding to the battery and a second identity corresponding to the medical device;
wirelessly transmitting, to the computer system from the client device, the first identity, the second identity, and the data; and
wirelessly receiving, by the client device from the computer system, a second expected lifetime of the medical device based on the data, including the charge state of the battery, and the second identity.

20. The system of claim 18, wherein the determination by the battery analysis program comprises:
accessing historical data to determine the expected charge state at the future time;
calculating, based on the historical data and the data including the remaining lifetime and the charge state of the battery, the expected charge state at the future time; and
providing the expected charge state at the future time to the client device, the battery management program and/or a configuration interface.

21. A computer program product comprising a non-transient, machine-readable medium, storing instructions which, when executed by at least one programmable processor, cause the at least one programmable processor to perform operations comprising:
wirelessly receiving, by a client device, data including a remaining lifetime and a charge state of a battery, the data determined by a battery diagnostic device comprising: a battery gauge, operatively connected to the battery, which measures a stored energy in the battery, and at least one transceiver operatively connected to the battery gauge through a microcontroller;
wirelessly relaying, by the client device, the received data to a computer system connected to a network to enable the computer system, executing a battery analysis program, to determine an expected charge state of the battery at a future time.

22. A method comprising:
determining a remaining lifetime and a charge state of a battery by a battery diagnostic device comprising: a battery gauge, operatively connected to the battery, which measures a stored energy in the battery, and at least one transceiver operatively connected to the battery gauge through a microcontroller;
wirelessly transmitting, by the transceiver to at least one client device, data including the remaining lifetime and the charge state.

23. The method of claim 22, wherein the battery diagnostic device further comprises the battery.

24. The method of claim 22, wherein the battery is external to the battery diagnostic device.

25. The method of claim 22, wherein the battery diagnostic device wirelessly transmits the data to at least one mobile client device.

26. The method of claim 25, the wirelessly transmitting comprising:
first transmitting, at a first time to a first mobile client device, first data including the remaining lifetime and the charge state of the battery; and
second transmitting, at a second time subsequent to the first time and to a second mobile client device, second data including the remaining lifetime and the charge state of the battery at the second time.

27. The method of claim 25, wherein the first transmitting and/or the second transmitting occur when the at least one mobile client device is within a transmission range of the battery diagnostic device.

28. The method of claim 25, wherein the at least one mobile client device is not a single, fixed-location, client device.

29. The method of claim 25, wherein the at least one mobile client device is at least one of a smartphone or a tablet computer.

30. A system comprising:
at least one client device; and
a battery diagnostic device comprising:
a battery gauge, operatively connected to a battery, and which measures a stored energy in the battery and determines a remaining lifetime and a charge state; and
at least one transceiver, operatively connected to the battery gauge through a microcontroller, and which is configured to wirelessly transmit data including the remaining lifetime and the charge state to the at least one client device.
